(19) United States
(12) Patent Application Publication
(10) Pub. No.: US 2014/0306705 A1
(43) Pub. Date: Oct. 16, 2014

(54) Operation of a Magnetic Resonance Apparatus with a Plurality of Transmission Antennas

(71) Applicants: Michael Köhler, Nurnberg (DE); Dominik Paul, Bubenreuth (DE)

(72) Inventors: Michael Köhler, Nurnberg (DE); Dominik Paul, Bubenreuth (DE)

(21) Appl. No.: 14/250,153

(22) Filed: Apr. 10, 2014

(30) Foreign Application Priority Data
Apr. 10, 2013 (DE) DE 102013206326.1

(51) Int. Cl. G01R 33/565; G01R 33/38

(52) U.S. Cl. CPC G01R 33/56572; G01R 33/38
USPC 324/309; 324/322

(57) ABSTRACT

A sequence of a plurality of pulses following one another in time is applied to an examination volume of a magnetic resonance apparatus using a plurality of transmission antennas. In order to transmit the respective pulse, the plurality of transmission antennas are actuated using a specific transmission signal by a control device of the magnetic resonance apparatus. The transmission signals have predetermined phase and amplitude relationships to one another. The phase and amplitude relationships of a first pulse of the sequence S differ from the phase and amplitude relationships of a second pulse of the sequence.

This application claims the benefit of DE 10 2013 206 326.1, filed on Apr. 10, 2013, which is hereby incorporated by reference in its entirety.

### BACKGROUND

The present embodiments relate to operation of a magnetic resonance apparatus.

Within the scope of recording methods in magnetic resonance examinations, sequences including a plurality of radiofrequency pulses may be used to excite an examination object (e.g., a human) arranged in an examination volume. The radiofrequency pulses have objects and/or functions that differ from another. The radiofrequency pulses follow one another in time. By way of example, in the case of spin echo-based sequences, there may be an excitation pulse and a refocusing pulse. There may also be a plurality of refocusing pulses. Examples of spin echo-based sequences are SE, TSE, SE-EPI and so on. As an alternative or in addition thereto, other radiofrequency pulses (e.g., fat saturation pulses or regional saturation pulses) may be present instead of the refocusing pulses.

To the extent that a plurality of different radiofrequency pulses are used within the scope of the recording method, the requirements and demands placed on these pulses may differ from one another. Examples of requirements and demands are the bandwidth and hence the duration of the respective pulse, the B1 homogeneity, the specific absorption rate (SAR) and so on. In the case of a magnetic resonance apparatus with only a single transmission antenna, the B1 homogeneity may not be influenced. The intensity of the pulse and the duration of the pulse are coupled to one another by the object and function of the respective pulse. The bandwidth of the pulse is determined by the duration and form thereof. The SAR is determined by the intensity of the pulse. However, as a result of the fact that the phase and amplitude relationships of the transmission signals from the transmission antennas may be set relative to one another, greater tuning options are provided in the case of a magnetic resonance apparatus with a plurality of transmission antennas. In the prior art, the phase and amplitude relationships of the transmission signals are, in general, tuned to one another such that a B1 homogeneity that is as high as possible emerges in the examination volume.

The maximum achievable B1 amplitude is restricted by system limitations of the magnetic resonance apparatus. These B1 limitations are load-dependent and therefore dependent on the examination object (e.g., a patient). Therefore, it may be the case that, given a selected pulse shape and pulse duration, for example, a desired flip angle is no longer achieved. In some cases, the pulse duration may be lengthened accordingly such that the desired flip angle is achieved due to the lengthening of the pulse duration. By contrast, in other cases, this procedure is not possible since the lengthening of the pulse is coupled to a reduction in the bandwidth. Such a reduction in the bandwidth may result in artifacts (e.g., due to the so-called chemical shift; in other words, the existence of different resonant frequencies for different types of tissue such as water and fat).

### SUMMARY AND DESCRIPTION

The scope of the present invention is defined solely by the appended claims and is not affected to any degree by the statements within this summary.

The present embodiments may obviate one or more of the drawbacks or limitations in the related art. For example, options by which the system limitations of the magnetic resonance apparatus may be employed to maximum effect are provided.

According to one or more of the present embodiments, in a method of operation, phase and amplitude relationships of a first one of the pulses differ from phase and amplitude relationships of a second one of the pulses. Denoting the pulses as first pulse and second pulse (and also as third pulse within the scope of the embodiments) serves to distinguish between the pulses. This is not intended to be connected with a more in-depth determination (e.g., relating to the sequence of the pulses in time). By way of example, the first pulse in the sequence may be carried out only after the second pulse. However, it is also possible for the numbering of the pulses to correspond to a sequence in time.

By way of example, as a result of the procedure according to one or more of the present embodiments, the first pulse and the second pulse may have B1 homogeneities that are different from one another and/or maximum B1 amplitudes that are different from one another.

For example, the phase and amplitude relationships of the first pulse may be selected such that a radiofrequency field generated in the examination volume or in a first sub-region of the examination volume using the first pulse is optimized with respect to a predetermined first criterion (e.g., a B1 homogeneity that is as high as possible).

In one embodiment, the first criterion of the control device of the magnetic resonance apparatus is fixedly predetermined. In this case, the pulses may also already be predefined in certain circumstances. However, the first criterion of the control device of the magnetic resonance apparatus may be predetermined by an operator of the magnetic resonance apparatus. In this case, the control device establishes for the transmission antennas the respective transmission signal of the first pulse taking into account the first criterion. Thus, a selection is not simply made from pulses stored in advance or from predefined phase and amplitude relationships, but the phase and amplitude relationships, for example, are established by calculation by the control device using a model of the magnetic resonance apparatus. This procedure offers a greater flexibility.

In one embodiment of the method of operation, the phase and amplitude relationships of the second pulse are also selected such that a radiofrequency field generated in the examination volume or in a second sub-region of the examination volume using the second pulse is optimized with respect to a predetermined second criterion (e.g., a maximum amplitude or a maximum amplitude given a predetermined maximum inhomogeneity). As a result, the second pulse may also be optimized in relation to the object to be achieved by the second pulse.

Analogously to the first pulse, the second criterion of the control device of the magnetic resonance apparatus may be predetermined by an operator of the magnetic resonance apparatus, and the control device may establish, for the transmission antennas, the respective transmission signal of the second pulse taking into account the second criterion.

Analogously to the first criterion, the second criterion may be determined as required. For example, the second criterion may be determined such that the radiofrequency field generated in the examination volume or in the second sub-region of the examination volume using the second pulse is optimized with respect to an amplitude, a homogeneity and an SAR as per weighting factors determined by the second criterion. In general, the weighting factors are positive real numbers that lie between 0 and 1 and add up to 1. If only the three aforementioned criteria are taken into account within the scope of the optimization, the three weighting factors add up to 1. If further criteria are also taken into account, the aforementioned statement that the sum of the weighting factors adds up to 1 applies to the totality of all weighting factors. The same embodiments may also be provided in relation to the first criterion.

As mentioned previously, an individual weighting factor has at least the value 0 and at most the value 1. In the singular case (e.g., when a single weighting factor has the value 1), it may therefore be possible for the second pulse only to be optimized with respect to the corresponding criterion (e.g., only the amplitude or the homogeneity or the SAR). In one embodiment, one of these weighting factors may have the value zero. In this case, depending on which one of the weighting factors has the value zero, only the amplitude and the homogeneity, only the amplitude and the SAR, or only the homogeneity and the SAR are taken into account in accordance with a respective weighting factors (e.g., differing from 0) when establishing the phase and amplitude relationships.

In the case where the radiofrequency field generated by the second pulse is only optimized in the second sub-region of the examination volume, the second sub-region may be fixedly prescribed for the control device. However, the second sub-region may be prescribed for the control device of the magnetic resonance apparatus by an operator of the magnetic resonance apparatus. This procedure leads to even greater flexibility. Here too, the same embodiment is also possible with respect to the first criterion.

As already mentioned above, the sequence of the pulses may be determined according to requirements. However, the second pulse may directly follow the first pulse within the sequence. Thus, no other pulse is applied to the examination volume using the transmission antennas between the first and the second pulse.

The object to be achieved by the first and the second pulse may be determined according to requirements. In a configuration relevant in practice, the first pulse is an excitation pulse, and the second pulse is a refocusing pulse.

In one embodiment, the sequence may include no further pulses except for the first and the second pulse. Alternatively, the sequence may include at least one third pulse. In one embodiment of the method of operation, the phase and amplitude relationships of the third pulse (or of the third pulses in the case of a plurality of third pulses) differ from the phase and amplitude relationships of the second pulse. However, the phase and amplitude relationships may but do not have to equal the phase and amplitude relationships of the first pulse. For example, the at least one third pulse may be a refocusing pulse.

In one embodiment, a magnetic resonance apparatus is provided.

According to one or more of the present embodiments, the control device of a magnetic resonance apparatus of the type set forth at the outset is embodied such that the phase and amplitude relationships of a first one of the pulses differ from the phase and amplitude relationships of a second one of the pulses.

The control device may be embodied such that, in operation, the control device carries out a method of operation according to at least one of the advantageous embodiments of the method of operation.

### BRIEF DESCRIPTION OF THE DRAWINGS

FIG. 1 shows one embodiment of a magnetic resonance apparatus;

FIG. 2 shows an exemplary sequence;

FIG. 3 shows exemplary amplitudes of pulses;

FIG. 4 shows exemplary phase relationships of pulses; and

FIG. 5 shows one embodiment of a control device.

### DETAILED DESCRIPTION

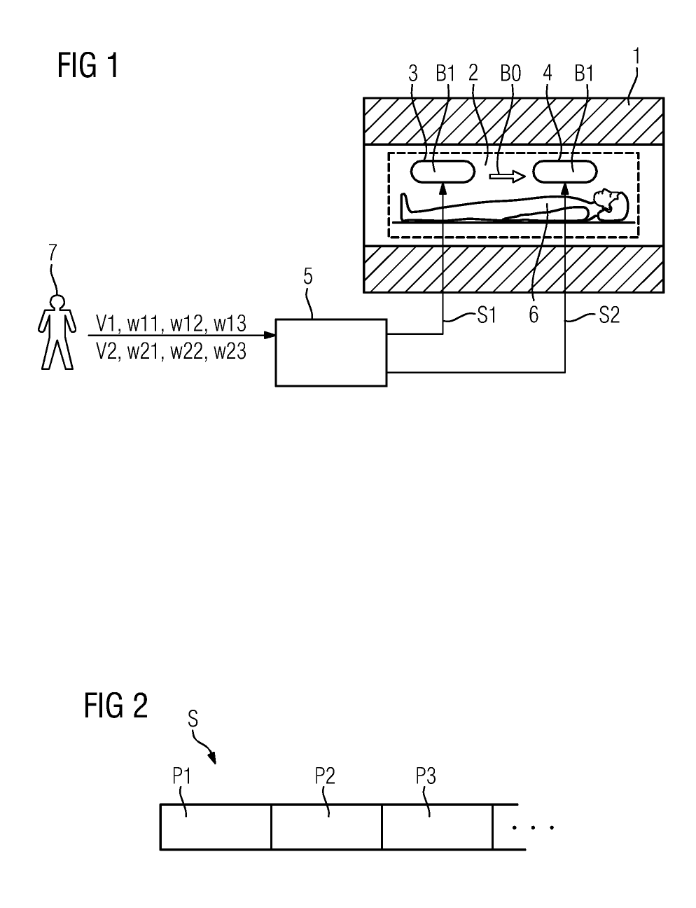

According to FIG. 1, one embodiment of a magnetic resonance apparatus includes a main magnet 1. A main magnetic field B0, which is constant in time and substantially homogeneous in space, is generated in an examination volume 2 using the main magnet 1. By way of example, the main magnetic field B0 has a magnetic field strength of 1.5 Tesla, 3.0 Tesla or 7.0 Tesla. Other magnetic field strengths may also be provided. The magnetic resonance apparatus also includes a plurality of transmission antennas 3, 4. As a minimum, two such transmission antennas 3, 4 are present, in accordance with the illustration from FIG. 1. However, there may also be more than two transmission antennas 3, 4. The magnetic resonance apparatus also includes a control device 5. Within the scope of operating the magnetic resonance apparatus, the control device 5 actuates different components of the magnetic resonance apparatus (e.g., the transmission antennas 3, 4).

Within the scope of operating the magnetic resonance apparatus, a sequence S is applied to the examination volume 2 using the transmission antennas 3, 4. In general, the application occurs in cooperation with gradient pulses. However, within the scope of one or more of the present embodiments, the gradient pulses are of secondary importance. Therefore, the gradient pulses are not explained in any more detail.

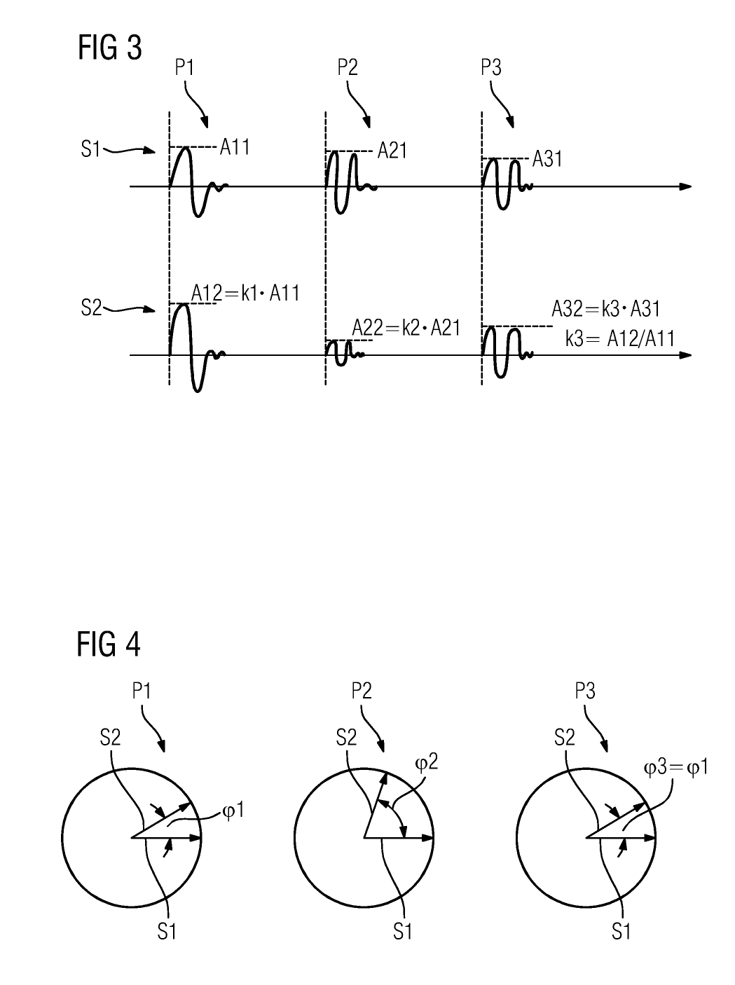

According to FIG. 2, the sequence S includes a plurality of pulses P1, P2, P3 following one another in time. As a result of applying the sequence S to the examination volume 2, an examination object 6 (e.g., a human) introduced into the examination volume 2 is excited to emit magnetic resonance signals. A sequence S with three pulses P1, P2, P3 is depicted in FIG. 2 in a purely exemplary manner. However, alternatively, the sequence S may likewise include more than three pulses P1, P2, P3. As a minimum, the sequence S includes at least two pulses P1, P2. In order to transmit the respective pulse P1, P2, P3, the transmission antennas 3, 4 are actuated by the control device 5 with a respective transmission signal S1, S2. According to FIG. 2 and also according to FIG. 3, the sequence of the pulses P1, P2, P3 in time continues to correspond to the numbering thereof. However, this is not mandatory.

FIG. 3 shows an exemplary sequence in time of the transmission signals S1, S2 from the transmission antennas 3, 4. According to FIG. 3, the transmission signals 51, S2 of the respective pulse P1, P2, P3 have defined amplitude relationships to one another. By way of example, the transmission signal S1 of the first pulse P1 for the one transmission antenna 3 has an amplitude A11. By contrast, the transmission signal S2 of the first pulse P1 for the other transmission antenna 4 has an amplitude A12. Analogously, the transmission signal S1 of the second pulse P2 for the one transmission antenna 3 has an amplitude A21. By contrast, the transmission signal S2 of the second pulse P2 for the other transmission antenna 4 has an amplitude A22. The transmission signal S1 of the third pulse P3 for the one transmission antenna 3 has an amplitude A31. By contrast, the transmission signal S2 of the third pulse P3 for the other transmission antenna 4 has an amplitude A32.

FIG. 4 shows an exemplary position and orientation of a radiofrequency field B1 generated by the transmission signals S1, S2 from the transmission antennas 3, 4 in relation to a coordinate system rotating in the transversal plane (e.g., in the plane orthogonal to the orientation of the main magnetic field B0) with the Larmor frequency. According to FIG. 4, the transmission signal S2 of the first pulse P1 for the other transmission antenna 4 has a phase offset φ1 with respect to the transmission signal S1 of the first pulse P1 for the one transmission antenna 3. The transmission signal S2 of the second pulse P2 for the other transmission antenna 4 has a phase offset φ2 with respect to the transmission signal S1 of the second pulse P2 for the one transmission antenna 3. The transmission signal S2 of the third pulse P3 for the other transmission antenna 4 has a phase offset φ3 with respect to the transmission signal S1 of the third pulse P3 for the one transmission antenna 3.

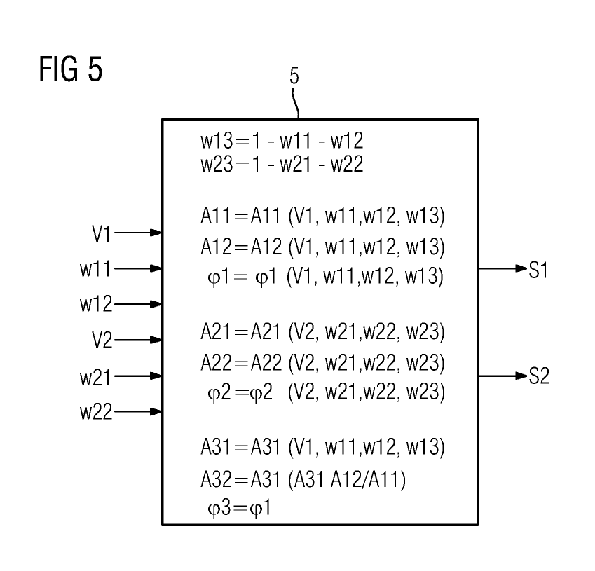

What emerges, for example, from the illustration according to FIG. 3 and FIG. 4, and also according to FIG. 5, is that the phase and amplitude relationships of the first pulse P1 are different from the phase and amplitude relationships of the second pulse P2. Thus, what applies, for example, is that a scaling factor k2 has a value different from a scaling factor k1, and/or the phase offset φ2 has a different value from the phase offset φ1.

According to FIG. 2 and also FIG. 3, the second pulse P2 directly follows the first pulse P1 within the sequence S. The first pulse P1 may be an excitation pulse. The second pulse P2 may be a refocusing pulse. Alternatively, the second pulse P2 may be, for example, a global or local fat saturation pulse. The third pulse P3 may be present, but it is not mandatory for the third pulse P3 to be present. If the third pulse P3 is present, the third pulse P3 may follow the second pulse P2 directly or indirectly. Like the second pulse P2, the third pulse P3 may be a refocusing pulse. Alternatively, the third pulse P3 may be, for example, a global or local fat saturation pulse. A plurality of third pulses P3, also having different functions, may also be present.

The phase and amplitude relationships of the third pulse P3 may be determined according to requirements. The phase and amplitude relationships of the third pulse P3 may differ from the phase and amplitude relationships of the second pulse P2. For example, in agreement with the illustration in FIG. 3, FIG. 4 and also in FIG. 5, the phase and amplitude relationships of the third pulse P3 may equal the phase and amplitude relationships of the first pulse P1.

The phase and amplitude relationships of the first pulse P1 may be selected such that the radiofrequency field B1 generated in the examination volume 2 or in a first sub-region V1 of the examination volume 2 using the first pulse P1 is optimized with respect to a predetermined first criterion. The first criterion may be determined such that the radiofrequency field B1 generated in the examination volume 2 or in the first sub-region V1 of the examination volume 2 using the first pulse P1 is optimized with respect to an amplitude, a homogeneity and a SAR as per weighting factors w11, w12, w13 determined by the first criterion. The weighting factors w11, w12, w13 may be determined as required. The weighting factors w11, w12, w13 may be fixedly prescribed for the control device 5 or may be prescribed by an operator 7 of the magnetic resonance apparatus. If the optimization takes place not in the whole examination volume 2 but only in the first sub-region V1 of the examination volume 2, the first sub-region V1 may be fixedly prescribed for the control device 5. The first sub-region V1 may also be prescribed by the operator 7.

Analogously, the phase and amplitude relationships of the second pulse P2 may be selected such that the radiofrequency field B1 generated in the examination volume 2 or in a second sub-region V2 of the examination volume 2 using the second pulse P2 is optimized with respect to a predetermined second criterion. The second criterion may be determined such that the radiofrequency field B1 generated in the examination volume 2 or in the second sub-region V2 of the examination volume 2 using the second pulse P2 is optimized with respect to an amplitude, a homogeneity and a SAR as per weighting factors w21, w22, w23 determined by the second criterion. The weighting factors w21, w22, w23 may be determined as required. The weighting factors w21, w22, w23 may be fixedly prescribed for the control device 5 or may be prescribed by the operator 7 of the magnetic resonance apparatus. If the optimization takes place not in the whole examination volume 2 but only in the second sub-region V2 of the examination volume 2, the second sub-region V2, analogously to the first sub-region V1, may be fixedly prescribed for the control device 5 or prescribed by the operator 7.

In one embodiment, the second sub-region V2 may be a sub-region that differs from the first sub-region V1. Alternatively, the second sub-region V2 may be identical to the first sub-region V1. In this case, the sub-region V1/V2 may be prescribed only once.

One or more of the present embodiments are explained above in conjunction with an embodiment of a magnetic resonance apparatus, in which two transmission antennas 3, 4 are present. However, the corresponding explanations also apply to embodiments of magnetic resonance apparatuses in which more than two transmission antennas 3, 4 are present.

The procedure according to one or more of the present embodiments is explained below based on a specific example.

The ZOOMit SPC sequence is a sequence known in magnetic resonance applications. This sequence has an excitation pulse, a first refocusing pulse and at least one further refocusing pulse. The excitation pulse corresponds to the first pulse P1 of one or more of the present embodiments. The phase and amplitude relationships may be determined for the excitation pulse such that this results in the highest possible B1 homogeneity. The first refocusing pulse corresponds to the second pulse P2 of one or more of the present embodiments. The phase and amplitude relationships may be determined for the first refocusing pulse such that this results in the highest possible B1 field strength. The at least one further refocusing pulse corresponds to the third pulse P3 of one or more of the present embodiments. Analogously to the excitation pulse, the phase and amplitude relationships may be determined for the further refocusing pulse (and all other pulses in the ZOOMit SPC sequence) such that this results in the highest possible B1 homogeneity. As a result of this, like in the prior art, a relatively homogeneous image quality may be achieved, while, however, what is simultaneously achieved in addition to the prior art, is that the first refocusing pulse produces the desired flip angle without having to increase the duration of the first refocusing pulse and, as a result thereof, having to reduce the bandwidth thereof.

The present embodiments have many advantages. For example, the procedure according to one or more of the present embodiments renders it possible to realize sequences S in which, in order to be used, the usual optimization criterion (e.g., highest possible B1 homogeneity) is to be discarded or at least weakened.

Although the invention is described and depicted in more detail by the exemplary embodiments, the invention is not restricted by the disclosed examples. Other variations may be derived from this by a person skilled in the art without departing from the scope of protection of the invention.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method of operation for a magnetic resonance apparatus, the method comprising:
applying a sequence of a plurality of pulses following one another in time to an examination volume of the magnetic resonance apparatus using a plurality of transmission antennas; and
actuating, by a control device of the magnetic resonance apparatus, the plurality of transmission antennas using a specific transmission signal in order to transmit a respective pulse of the plurality of pulses,
wherein the transmission signals have predetermined phase and amplitude relationships to one another, and
wherein the phase and amplitude relationships of a first pulse of the plurality of pulses differ from the phase and amplitude relationships of a second pulse of the plurality of pulses.

2. The method of operation of claim 1, wherein the phase and amplitude relationships of the first pulse are selected such that a radiofrequency field generated in the examination volume or in a sub-region of the examination volume using the first pulse is optimized with respect to a predetermined criterion.

3. The method of operation of claim 2, wherein the predetermined criterion of the control device of the magnetic resonance apparatus is predetermined by an operator of the magnetic resonance apparatus, and
wherein the method further comprises establishing, by the control device, for the plurality of transmission antennas, the respective transmission signal of the first pulse taking into account the criterion.

4. The method of claim 1, wherein the phase and amplitude relationships of the second pulse are selected such that a radiofrequency field generated in the examination volume or in a sub-region of the examination volume using the second pulse is optimized with respect to a criterion.

5. The method of operation of claim 4, wherein the criterion of the control device of the magnetic resonance apparatus is predetermined by an operator of the magnetic resonance apparatus, and
wherein the method further comprises establishing, by the control device, for the plurality of transmission antennas, the respective transmission signal of the second pulse taking into account the criterion.

6. The method of operation of claim 4, wherein the criterion is determined such that the radiofrequency field generated in the examination volume or in the sub-region of the examination volume using the second pulse is optimized with respect to an amplitude, a homogeneity and an SAR as per weighting factors determined by the criterion.

7. The method of operation of claim 4, wherein the sub-region is prescribed for the control device of the magnetic resonance apparatus by an operator of the magnetic resonance apparatus.

8. The method of operation of claim 1, wherein the second pulse directly follows the first pulse within the sequence.

9. The method of operation of claim 8, wherein the first pulse is an excitation pulse, and the second pulse is a refocusing pulse.

10. The method of operation of claim 1, wherein the sequence comprises at least one third pulse, and
wherein phase and amplitude relationships of the at least one third pulse differ from the phase and amplitude relationships of the second pulse.

11. The method of operation of claim 10, wherein the phase and amplitude relationships of the at least one third pulse equal the phase and amplitude relationships of the first pulse.

12. The method of operation of claim 10, wherein the at least one third pulse is a refocusing pulse.

13. A magnetic resonance apparatus comprising:
a plurality of transmission antennas operable to apply a sequence of a plurality of pulses following one another in time to an examination volume of the magnetic resonance apparatus; and
a control device configured to actuate the plurality of transmission antennas using a specific transmission signal in order to transmit the respective pulse,
wherein the transmission signals have predetermined phase and amplitude relationships to one another, and
wherein the control device is configured such that the phase and amplitude relationships of a first pulse of the plurality of pulses differ from the phase and amplitude relationships of a second pulse of the plurality of pulses.

14. The magnetic resonance apparatus of claim 13, wherein the phase and amplitude relationships of the first pulse are selected such that a radiofrequency field generated in the examination volume or in a sub-region of the examination volume using the first pulse is optimized with respect to a predetermined criterion.

15. The magnetic resonance apparatus of claim 14, wherein the predetermined criterion of the control device of the magnetic resonance apparatus is predetermined by an operator of the magnetic resonance apparatus, and
wherein the control device is further configured to establish, for the plurality of transmission antennas, the respective transmission signal of the first pulse taking into account the criterion.

16. The magnetic resonance apparatus of claim 13, wherein the phase and amplitude relationships of the second pulse are selected such that a radiofrequency field generated in the examination volume or in a sub-region of the examination volume using the second pulse is optimized with respect to a criterion.

17. The magnetic resonance apparatus of claim 16, wherein the criterion of the control device of the magnetic resonance apparatus is predetermined by an operator of the magnetic resonance apparatus, and
wherein the control device is further configured to establish, for the plurality of transmission antennas, the respective transmission signal of the second pulse taking into account the criterion.
